(19) United States
(12) Patent Application Publication
(10) Pub. No.: US 2009/0134010 A1
(43) Pub. Date: May 28, 2009

(54) SPUTTERING APPARATUS AND SPUTTERING METHOD

(75) Inventors: Masahiro Shibamoto, Yokohama-shi (JP); Kazuto Yamanaka, Sagamihara-shi (JP); Hitoshi Jimba, Fuchu-shi (JP); David Djulianto Djayaprawira, Fuchu-shi (JP)

Correspondence Address: FITZPATRICK CELLA HARPER & SCINTO, 30 ROCKEFELLER PLAZA, NEW YORK, NY, 10112, US

(73) Assignee: CANON ANELVA CORPORATION, Kawasaki-shi (JP)

(21) Appl. No.: 12/274,022

(22) Filed: Nov. 19, 2008

Related U.S. Application Data
(63) Continuation of application No. PCT/JP2007/072625, filed on Nov. 22, 2007.

(51) Int. Cl. C23C 16/44

(52) U.S. Cl. 204/192.1; 204/298.07; 204/298.01

(57) ABSTRACT

A sputtering apparatus according to the present invention includes a substrate holding means for holding substrates and gas introducing routes having a plurality of gas jetting ports arranged at a plurality of places surrounding the substrates, and characterized in that at least one of the gas introducing routes is provided with a gas introduction connecting port, and the number of gas jetting ports provided in at least one of the gas introducing routes with the gas introduction connecting port is smaller than the number of gas jetting ports provided in the other gas introducing routes without the gas introduction connecting ports, or an aperture of each of the gas jetting ports provided in at least one of the gas introducing routes with the gas introduction connecting port is smaller than an aperture of each of the gas jetting ports provided in the other gas introducing routes without the gas introduction connecting ports.

### CROSS-REFERENCES TO RELATED APPLICATIONS

This application is a continuation application of International Application No. PCT/JP2007/072625, filed on Nov. 22, 2007, the entire contents of which are incorporated by reference herein.

### TECHNICAL FIELD

The present invention relates to a sputtering apparatus and in particular a sputtering method which are capable of forming films on substrates by reactive sputtering using a reactive gas.

### BACKGROUND ART

In a sputtering apparatus, a target material attached to a cathode is bombarded with ions whereby particles of the target material (i.e. sputtered particles) are ejected onto a substrate being arranged as facing the target to form a thin film of the target material on the substrate. Accordingly, in a sputtering apparatus, a gas for inducing sputtering (i.e. a sputtering gas or a plasma producing gas) within a vacuum chamber is introduced into the vacuum chamber, and ions for producing sputtered particles of the target material are generated by producing plasma by supplying energy to the target by means of supplying high-frequency power or applying DC voltage. The sputtered particles of the target material ejected onto the surface of the substrate will result in making the target material be deposited on the surface of the substrate.

With respect to a sputtering apparatus as the one described above, a typical one would be a reactive sputtering apparatus. In a reactive sputtering apparatus (hereinafter to be referred to as “sputtering apparatus”), a reactive gas such as oxygen, nitrogen, etc. is introduced into a chamber along with an inactive gas (i.e. sputtering gas) such as argon (Ar) which is to induce sputtering. In such sputtering apparatus, a target material is bombarded with argon ions in a plasma being produced, whereby particles of the target material will be ejected and react with the reactive gas as mentioned above, resulting in making the resultant reactant be deposited on the surface of a substrate to form a film. In addition, when the reactive gas is dense, a compound layer will be formed on the surface of the target material due to the reactive gas, and by sputtering the target material in such state, the reactant with a desired composition will be deposited on the substrate.

Patent Document 1 discloses a sputtering apparatus which supplies reactive gases simultaneously and uniformly from a semiconductor substrate and from the circumference of a sputtering source, respectively. Patent Document 2 discloses a sputtering apparatus provided with an introducing mechanism that brings a reactive gas to flow outwardly from a central part of a cathode unit along the surface of a target. Patent Document 3 discloses a reactive sputtering apparatus which uniformizes supply of processing gas when forming a film on a large-size substrate, by which a film with good film thickness can be obtained.

Patent Document 1: Japanese Patent Application Laid-Open No. H5-243155

Patent Document 2: Japanese Patent Application Laid-Open No. 2004-346406

Patent Document 3: Japanese Patent Application Laid-Open No. 2001-107228

Even with the above mentioned conventional art, there are cases in which uniformity of the processing gas cannot be realized.

### DISCLOSURE OF THE INVENTION

In order to resolve the above-mentioned problem, the present invention provides a sputtering apparatus including a substrate holding means for holding substrates and gas introducing routes having a plurality of gas jetting ports arranged at a plurality of places surrounding the substrate, the sputtering apparatus characterized in that at least one of the gas introducing routes is provided with a gas introduction connecting port, and the number of gas jetting ports provided in at least one of the gas introducing routes with the gas introduction connecting port is smaller than the number of gas jetting ports provided in the other gas introducing routes without the gas introduction connecting ports, or an aperture of each of the gas jetting ports provided in at least one of the gas introducing routes with the gas introduction connecting port is smaller than an aperture of each of the gas jetting ports provided in the other gas introducing routes without the gas introduction connecting ports. Here, the processing gas indicates an inactive gas or a reactive gas.

According to the present invention, it is possible to uniformly introduce a processing gas with respect to a substrate. Therefore, it is possible to improve uniformity of the film characteristics.

### BRIEF DESCRIPTION OF THE DRAWINGS

FIG. 1 is a sectional view of a gas introducing mechanism according to one embodiment of the present invention;

FIG. 2 is a sectional view of a vacuum chamber according to one embodiment of the present invention;

FIG. 3 is another sectional view of a gas introducing mechanism according to one embodiment of the present invention;

FIG. 4 is a plane view showing a schematic structure of a thin film forming apparatus according to one embodiment of the present invention;

FIG. 5 is a schematic front view of a substrate holder and a traveling means in the thin film forming apparatus shown in FIG. 4;

FIG. 6 is a schematic sectional side view of the substrate holder and the traveling means in the thin film forming apparatus shown in FIG. 4;

FIG. 7 is a schematic sectional side view which explains a structure of the thin film forming apparatus shown in FIG. 4;

FIG. 8 is a sectional view of a gas introducing mechanism according to another embodiment of the present invention; and

FIG. 9 is a diagram showing changes in uniformity (%) of a produced thin film based on changes in the number and apertures (mm) of gas jetting ports of the gas introducing mechanism according to the present invention.

### DESCRIPTION OF SYMBOLS

100 gas introducing mechanism
101 gas inlet port
102 gas introduction connecting ports
103 gas introducing routes
104 gas jetting ports
105 substrates

### BEST MODES FOR CARRYING OUT THE INVENTION

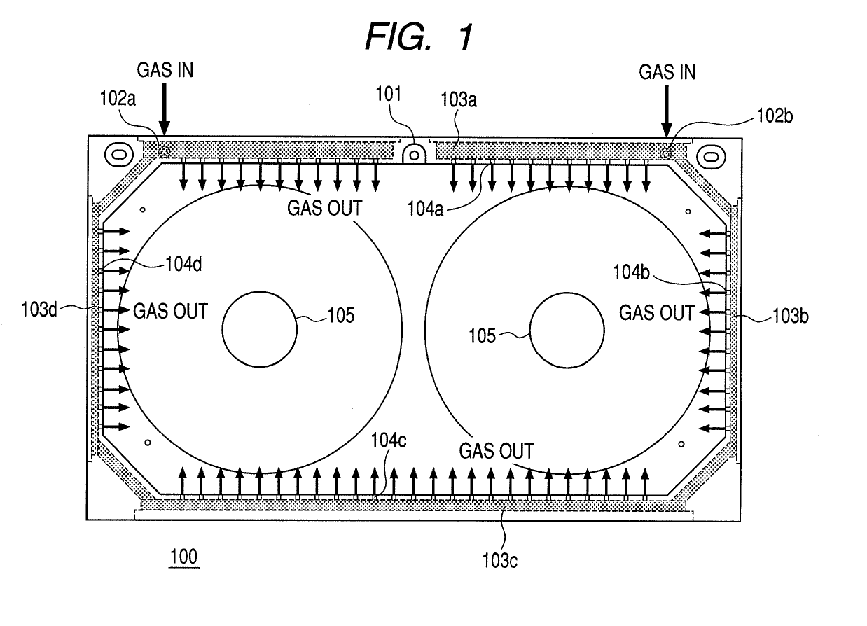

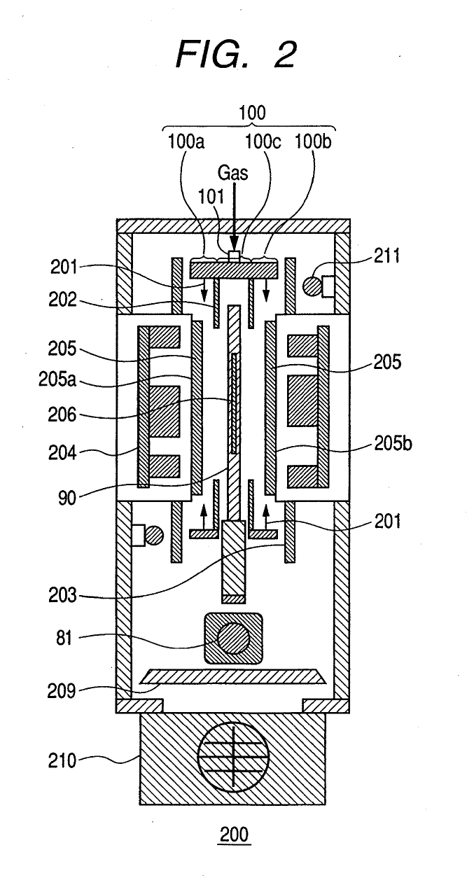

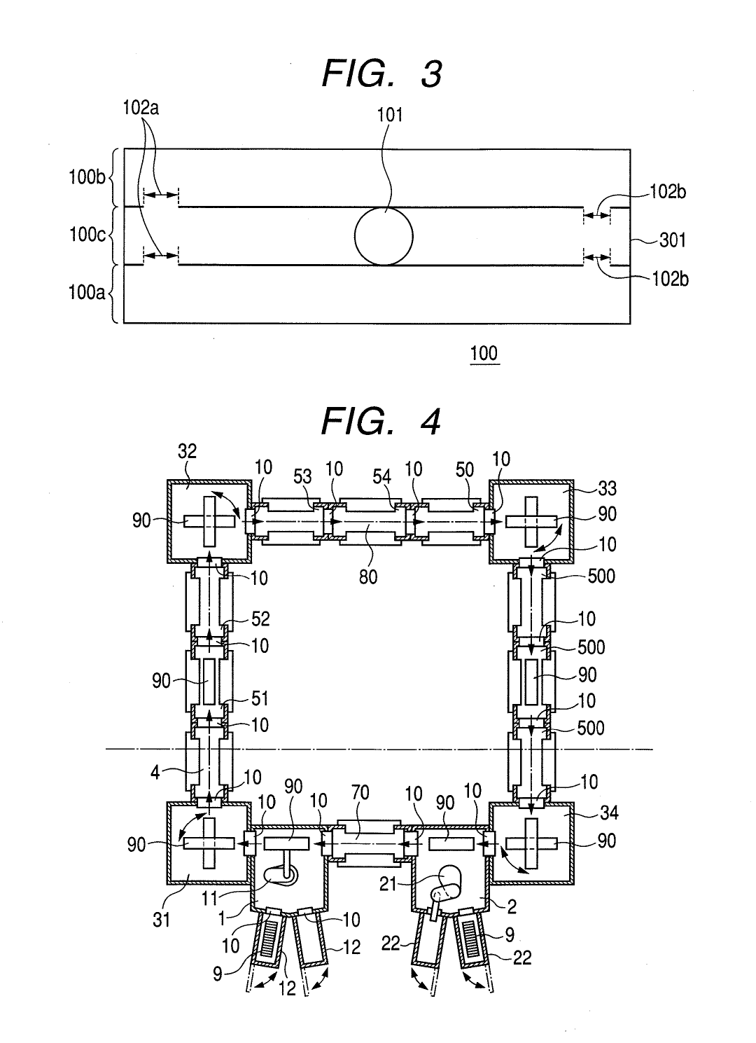

In the following, an embodiment of the present invention will be described. In the following description, a thin film forming apparatus for producing a data recording disk will be referred to as one example of a thin film forming apparatus. FIG. 1 is a sectional view of a gas introducing mechanism 100 when viewed from a direction perpendicular to the surface of a substrate. As shown in FIG. 1, in the gas introducing mechanism 100, two substrates 105 being held by a substrate holder (shown in FIG. 2) are supported in a longitudinal state (vertical posture), while they are arranged symmetrically with respect to a central axis of the gas introducing mechanism 100. The substrates 105 are overall in shapes of thin circular discs. The gas introducing mechanism 100 shown in FIG. 1 is provided with a gas inlet port 101 in the upper center portion, and with gas introduction connecting ports (Gas IN) 102a and 102b in the upper left and upper right portions, respectively. The gas introduction connecting ports 102a and 102b are provided on a gas introducing route 103a, and a gas supplied from a gas supply source will enter into the gas introducing mechanism 100 from the gas inlet port 101 to reach the gas introduction connecting ports 102a and 102b passing through a gas pipe (“100c” shown in FIG. 3). In this gas introducing mechanism 100, it is arranged such that a processing gas entering from the gas introduction connecting port 102a provided in the upper left portion will flow along the gas introducing routes 103a to 103d and jet out onto the substrates 105 from gas jetting ports 104a to 104d provided in the gas introducing routes 103a to 103d. The gas introducing routes 103a to 103d have hollow structures. Likewise, it is arranged such that a processing gas entering from the gas introduction connecting port 102b provided in the upper right portion will flow along the gas introducing routes 103a to 103d and jet out onto the substrates 105 from the gas jetting ports 104a to 104d provided in the gas introducing routes 103a to 103d. In this embodiment, it is possible to arrange two substrates 105, and the gas introducing routes 103a to 103d are provided in an approximate rectangular arrangement in a way entirely surrounding the two substrates 105. In FIG. 1, four gas introducing routes 103a to 103d are shown, and these gas introducing routes 103a to 103d are provided with gas jetting ports 104a to 104d arranged at a plurality of places surrounding both of the two substrates 105. However, such arrangement can have change of design where appropriate in different embodiments. For example, it is possible to arrange the gas jetting ports 104 such that the processing gas can be supplied with respect to a plurality of substrates as a whole from one facing direction. It is also possible to arrange such that one facing gas introducing route 103 has more gas jetting ports 104 than the other. Furthermore, it is also possible to arrange such that one facing gas introducing route 103 has gas jetting ports 104 with larger apertures than those of the other.

Here, as explained on page 38 of Reference 1, for example, the conductance of the gas introducing route is proportional to a sectional area “A” of the gas introducing route, and is inversely proportional to a length “l” of the gas introducing route. Therefore, the gas introducing route 103a has larger conductance than the gas introducing route 103c, for the route length of the gas introducing route 103a from the gas introduction connecting port 102 is shorter than the route length of the gas introducing route 103c from the gas introduction connecting port 102. As a result, there will be variation in concentration distribution of gas on the substrates 105 between the gas jetted out from the gas jetting ports 104a of the gas introducing route 103a provided in the upper unit and the gas jetted out from the gas jetting ports 104c of the gas introducing route 103c provided in the lower unit.

[Reference 1] “Shinkuu Gijutu Jitsumu Tokuhon (Vacuum Technique Practice Reader)” written by Katsuya Nakayama, Ohmsha, Ltd.

In order to resolve such problem, in the present embodiment, the gas jetting ports 104 provided in places where the route lengths from the respective gas introduction connecting ports 102a and 102b are short are set to have smaller apertures than those of the gas jetting ports 104 provided in places where the route lengths from the respective gas introduction connecting ports 102a and 102b are long. Thereby, it is possible to uniformly supply the gas to the substrates 105 with both of the gas introducing routes 103a and 103c provided in the upper unit and in the lower unit, respectively. Other than that, in the gas introducing route 103a provided in the upper unit and in the gas introducing route 103c provided in the lower unit of the gas introducing mechanism 100, in order to uniformize the gas to be jetted out, it is also possible to arrange such that the number of gas jetting ports 104a in the gas introducing route 103a provided in the upper unit is reduced to a smaller number than that of the gas jetting ports 104c of the gas introducing route 103c provided in the lower unit. In the present embodiment, the gas introducing mechanism 100 is provided with 11 gas jetting ports 104a with respect to each of the gas introduction connecting ports 102a and 102b in the upper unit gas introducing route 103a. On the other hand, in the lower unit gas introducing route 103c, a total of 25 gas jetting ports 104c are provided. In the present embodiment, two substrates 105 are held by the gas introducing mechanism 100 that is structured in a way such that the gas can be supplied to each of the substrates 105 mainly by 11 of the gas jetting ports 104a provided in the upper unit gas introducing route 103a and by 12 of the gas jetting ports 104c provided in the lower unit gas introducing route 103c. However, since the conductance differs depending on the kind of gas to be used, it is also possible to set the number of the gas jetting ports 104 and the apertures thereof in advance to comply with the kind of gas to be used.

In the present embodiment, although the gas introduction connecting ports 102 are provided only in the gas introducing route 103a in the upper unit, it is also possible to arrange the gas introduction connecting ports 102 in both of the gas introducing route 103a provided in the upper unit and the gas introducing route 103c provided in the lower unit. In this case, however, considering the conductance of the gas introducing route mentioned above, it is preferable that the gas introduction connecting port 102 provided in the gas introducing route 103a in the upper unit and the gas introduction connecting port 102 provided in the gas introducing route 103c in the lower unit are arranged symmetrically. In addition, it is also possible to arrange the gas introduction connecting ports in the gas introducing route 103d provided on the left side and in the gas introducing route 103b provided on the right side, respectively. In this case also, considering the conductance of the gas introducing route, it is preferable that these gas introduction connecting ports are arranged symmetrically.

FIG. 2 is a sectional view of a vacuum chamber 200 when viewed from a side direction, and it shows a positional relation of the gas introducing mechanism 100 as provided within the chamber 200. The vacuum chamber 200 will be described to begin with. The vacuum chamber 200 is provided with a turbo-molecular pump 210 and a main valve 209, and these components are making up a gas exhaust system of the vacuum chamber 200. A carrier magnet 81 is arranged in the upper side of the main valve 209, and further in the upper side of the carrier magnet 81, a substrate holder 90 for holding substrates 206 is arranged. The substrate holder 90 can be made carriable along the carrier magnet 81 by using the magnetic force of the carrier magnet 81.

As shown in FIG. 2, the gas introducing mechanism 100 is structured as having a space formed by a pair of center shields 202 in the central part in its width direction. The substrate holder 90 in the upper side of the carrier magnet 81 is arranged in this space. The substrate holder 90 is capable of holding a plurality of substrates on the same plane. Target placement tables 205a and 205b are arranged as having the substrate holder 90 positioned in between, and targets 205 are placed on the target placement tables 205a and 205b, respectively. Magnets 204 are placed behind the targets 205, respectively. The gas introducing mechanism 100 includes a left side portion 100a of the gas introducing mechanism 100 and a right side portion 100b of the gas introducing mechanism 100 which enable a gas 201 supplied from the gas inlet port 101 to be introduced inside the gas introducing mechanism 100. An arrow shown in FIG. 2 indicates a flow of the gas 201. Both of the left side portion 10a of the gas introducing mechanism 100 and the right side portion 100b of the gas introducing mechanism 100 have gas introducing routes, respectively. These gas introducing routes have hollow structures and together they construct a pair of gas introducing routes arranged symmetrically in a way sandwiching both sides of the substrate holder 90. The targets 205 and the substrates being held by the substrate holder 90 are communicating through the hollow structures of the gas introducing routes. In between the left side portion 10a and the right side portion 100b of the gas introducing mechanism 100, a center portion 100c having the gas inlet port 101 is being arranged. By these two lines of gas introducing routes, it is possible to introduce the gas from both sides of the plurality of substrates 206 being held by the substrate holder 90. In this way, the gas introducing mechanism according to the present invention has two facing gas introducing routes sandwiching at least one substrate 206 being held by the substrate holder 90.

As mentioned above, the gas introducing mechanism 100 is provided with the center shields 202. The center shields 202 are arranged in a way sandwiching a part of the substrate holder 90. However, it is preferable that they will not overlap with the projection plane of the substrate 206, which is being held by the substrate holder 90, in the normal direction of the substrate. In a way opposing the respective center shields 202, outer shields 203 are extending from the vicinities of both ends of the targets 205, respectively, the targets 205 having the magnets 204 placed behind them. By such arrangement, it is possible to prevent the gas 201 from being diffused, while being able to uniformly supply the gas with respect to the substrates 206. A bake heater 211 functions to evaporate possible impurities (e.g. water, etc.) attached inside the vacuum chamber 200 or to shields, etc. inside the chamber, by heating.

In the following, an operation of the vacuum chamber shown in FIG. 2 will be described. First, before the substrate holder 90 is carried inside the vacuum chamber 200, it is necessary to set up a mode where an inactive gas Ar to be supplied from the unshown gas supply source through the gas introducing mechanism 100 should flow inside the chamber 200 at all times. Therefore, the main valve 209 is set to be in a half-open state or in other words in a state of intermediate stop in order to be able to control pressure. By doing so, the Ar gas supplied from the gas introducing mechanism 100 will pass thorough the vicinity of the targets 205 and flow into the turbo-molecular pump or cryopump 210 to be exhausted. Next, a gate valve of the vacuum chamber 200 is to be opened whereby the substrate holder 90 being kept in another chamber is to be carried inside the vacuum chamber 200. Next, an active gas (e.g. oxygen, nitrogen, etc.), which is being supplied from the unshown gas supply source through the gas introducing mechanism 100, is to be fed to the vicinities of the targets 205. At this time also, Ar is flowing constantly. After a lapse of a predetermined time period when the pressure should become even, plasma discharge is to be performed using an unshown power source. The ions in the plasma will be attracted toward each target 205 due to a cathode (not shown) arranged in the opposite side of the sputtering surface of the target 205, and then sputter the target 205, by which particles of the target material will be ejected out. The ejected particles of the target material will react with the active gas, as a result of which the resultant reactant will be deposited on the surface of the substrate 206 to form a film. After the discharge is completed, supply of inactive gas is to be shut off, a gate valve is to be opened, and the substrate holder 90 is to be carried off. Instead of having both the inactive gas Ar and the active gas flowing at all times, it is possible to control them in the same way as with the active gas.

FIG. 3 is a sectional view of the gas introducing mechanism 100 according to the present invention, when viewed from directly above. The gas inlet port 101 for introducing a processing gas is provided in the upper unit of the gas introducing mechanism 100. The processing gas introduced from the gas inlet port 101 will flow along the center portion 100c (gas pipe) of the gas introducing mechanism 100 equally toward both ends 301 of the gas introducing mechanism 100 from the gas inlet port 101, and it will branch off at the gas introduction connecting ports 102a and 102b provided in the vicinity of the end 301. The processing gas will flow along the left side portion 10a and the right side portion 100b of the gas introducing mechanism 100 via the gas introduction connecting ports 102a and 102b shown in FIG. 1, in a way surrounding each substrate 105. FIG. 3 shows the left side portion 10a, the right side portion 100b, and the inside of the center portion 10c of the gas introducing mechanism 100, when viewed from the upper surface side. The left side portion 10a and the right side portion 100b of the gas introducing mechanism 100 when viewed from the side surface side are shown as gas introducing routes 103, etc. in FIG. 1.

FIG. 4 is a plane view showing a schematic structure of a thin film forming apparatus 400 according to the embodiment of the present invention. In the apparatus of the present embodiment, a plurality of vacuum chambers 1, 2, 4, 31 to 34, 50 to 54 and 500 are arranged in series along a square outline. Each vacuum chamber is a vacuum vessel having a dedicated or common exhaust system for exhausting gas. In the boundaries of each vacuum chamber, gate valves 10 are being arranged. Substrates 9 should be able to be carried as being held by the substrate holder 90. A traveling path 80 in a square form is arranged along the plurality of serially arranged vacuum chambers, and a traveling means for moving the substrate holder 90 along the traveling path 80 is provided. By this traveling means, the substrate holder 90 is able to be carried inside each chamber while holding the substrates 9.

Among the plurality of vacuum chambers, one of the two vacuum chambers arranged at one side of the square arrangement is a load lock chamber 1 whereby loading of the substrates 9 on the substrate holder 90 is performed and the other of the two is an unload lock chamber 2 whereby retrieval of the substrates 9 from the substrate holder 27 is performed. With respect to the square form traveling path 80, a part of it in between the load lock chamber 1 and the unload lock chamber 2 functions as a return traveling path which is used when the unload lock chamber 2 is to return the substrate holder 27 to the load lock chamber 1. Inside the load lock chamber 1, a loading robot 11 for loading the substrates 9 on the substrate holder 90 is provided. The loading robot 11 is structured in such a way as to take in two of the substrates 9 at the same time from a loading substrate stocker and load the substrates 9 on the substrate holder 27 using its arm. On the other hand, the unload lock chamber 2 is provided with a retrieving robot 21 which is structured in the same way as the loading robot 11. The retrieving robot 21 takes in two substrates 9 at the same time from the substrate holder 90 and place the substrates 9 in a retrieving substrate stocker using its arm. The reason for adopting the loading substrate stocker is because, if all of the substrates inside a loading substrate chamber 12 are placed in the loading substrate stocker, it will be possible to load the subsequent substrates in the loading substrate chamber 12, whereby productivity can be improved. The retrieving substrate stocker is adopted for the same kind of reason, and thus a retrieving substrate chamber 22 is provided.

The vacuum chambers 4, 31 to 34, 50 to 54 and 500 arranged at the other three sides of the square arrangement are vacuum chambers which perform various processes on the substrates 9. The vacuum chambers 31 to 34 in the corners of the square arrangement are defined as turning chambers 31, 32, 33 and 34 each provided with a turning means for making the substrate holder 90 being carried make a 90-degree turn. In the present embodiment, the vacuum chamber 500 is defined as a complementary chamber 500. This complementary chamber 500 can be structured as a chamber for cooling the substrates 9 where necessity. After going through the complementary chamber 500 and then the last turning chamber 34, the substrates 9 will arrive at the unload lock chamber 2.

In FIG. 4, the substrate holder 90 holding the substrates 9 is carried through the thin film forming apparatus 400 in a clockwise direction. The very first vacuum chamber for processing that the substrates 9 held by the substrate holder 90 reach is a preheating chamber 4 which functions to preheat the substrates 9 to a predetermined temperature prior to film forming. After being preheated at the preheating chamber 4, the substrates 9 will be carried through one or more film forming chambers which are to form predetermined thin films on the surfaces of the substrates 9. In the present embodiment, a plurality of film forming chambers 51, 52, 53, 54 and 50, which are arranged in series along the sides of a square, are being used. The film forming chambers 51, 52, 53 and 54 are film forming sputtering chambers which form films on the substrates by sputtering, whereas the film forming chamber 50 is a protective film forming chamber. Among the preheating chamber 4, the film forming chambers 51 to 54 and the protective film forming chamber 50, at least one of those film forming processing chambers can adopt the vacuum chamber 200 which is applicable to the present invention. In addition, each of the film forming chambers 51 to 54 can select one vacuum processing chamber from among a physical vapor deposition (PVD) chamber, a chemical vapor deposition (CVD) chamber, a physical etching chamber, a chemical etching chamber, a substrate heating chamber, a substrate cooling chamber, an oxidation treatment chamber, a reduction treatment chamber and an ashing chamber, to adopt. The film forming processing chamber and at least one vacuum processing chamber are connected without being exposed to air.

A film delamination preventing chamber 70 is provided in between the load lock chamber 1 and the unload lock chamber 2. As with the chambers 51, 52, 53, 54 and 50 for forming thin films, the film delamination preventing chamber 70 is also a kind of vacuum chamber that is provided with an exhaust system (not shown).

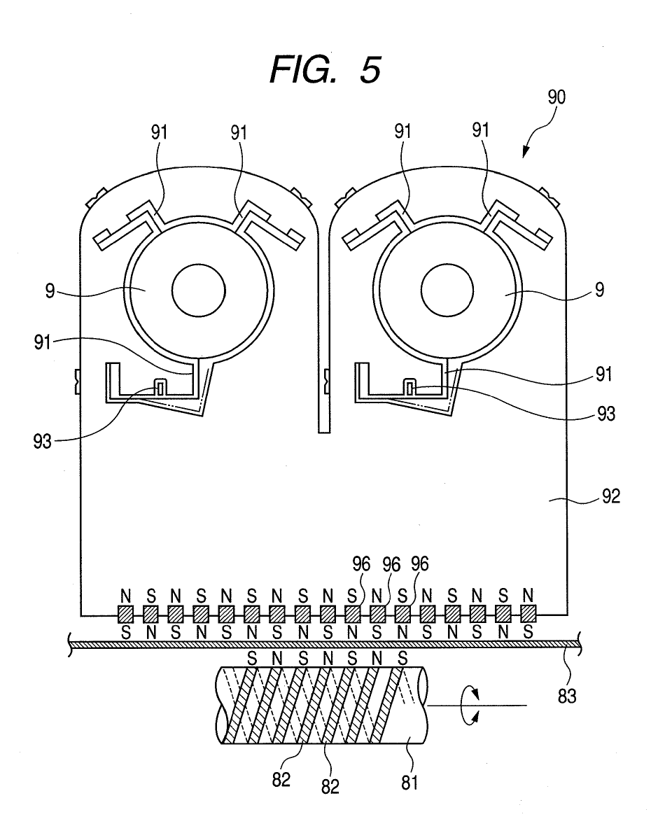

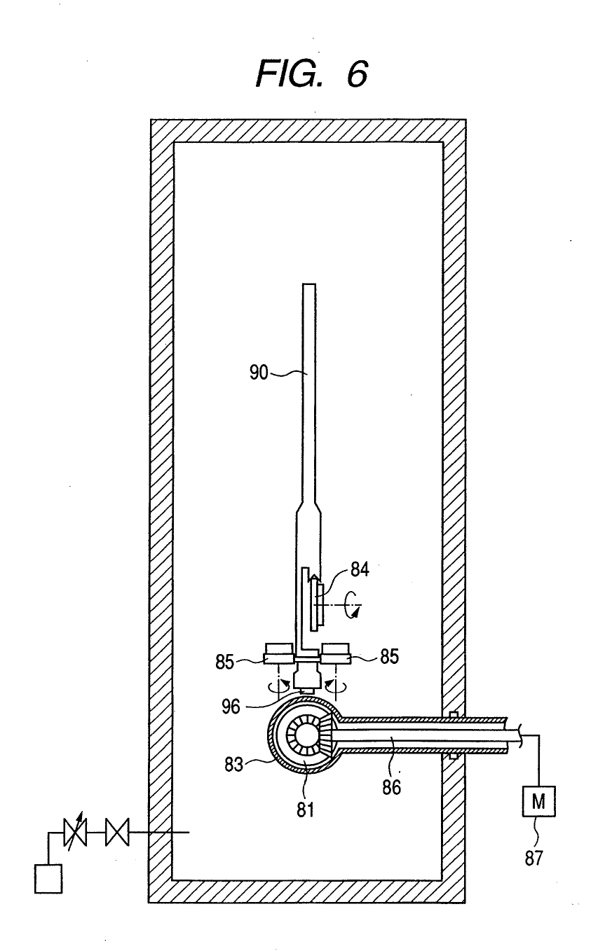

In the thin film forming apparatus 400 according to the present embodiment, the traveling means should make the substrate holder 90 holding the substrates 9 move along the traveling path 80 in a clockwise direction in order to have the substrates 9 sequentially processed. As an example of the traveling means, a traveling means whereby the substrate holder 90 moves in a linear manner, etc., will be described with reference to FIG. 5 and FIG. 6.

FIG. 5 and FIG. 6 are diagrams for explaining structures of the substrate holder 90 and the traveling means provided in the apparatus shown in FIG. 4, while FIG. 5 is a schematic front view and FIG. 6 is a schematic sectional side view of them.

The substrate holder 90 is structured as including a substrate holder main body 92 and holding nails 91 arranged in the rim of the substrate holder main body 92. A total of six holding nails 91 are being provided, while each three of them as a leash hold a single substrate 9. Among the three holding nails 91 in a leash, the one positioned on the lower side is a movable holding nail 91. Therefore, a lever 93 for pressing down this holding nail 91 against the elasticity of it is being provided. In loading each substrate 9 onto the substrate holder 90, the holding nail 91 on the lower side is to be pressed down by the lever 93 and the substrate 9 is to be positioned inside a circular opening of the substrate holder main body 92. Then, the lever 93 is to be placed back whereby the holding nail 91 on the lower side is to return to its original position. As a result, each substrate 9 is to be locked by the three holding nails 91, and thus, two substrates 9 are to be held by the substrate holder 90. In a case of retrieving each substrate 9 from the substrate holder 90, the operation will be the exact opposite. In addition, the substrate holder 90 is supposed to be able to hold two substrates 9 at the same time. As shown in FIG. 5, the substrate holder 90 according to the first embodiment of the present invention is provided with a number of magnets (hereinafter to be referred to as “holder side magnets”) 96 in its lower end portion. Each of the holder side magnets 96 has magnetic poles on the upper and lower faces. These holder side magnets 96 are arranged in such a way as to have alternately different polarities along the arranging direction as shown in FIG. 5.

The carrier magnet 81 is provided on the lower side of the substrate holder 90 across a bulkhead 83. The carrier magnet 81 is a member with a shape of a round bar, and as shown in FIG. 5, it has elongated magnets (hereinafter to be referred to as “roller side magnets”) 82 extending in a spiral manner. The roller side magnets 82 are provided in two as having different magnetic poles between each other, and they are arranged in a duplex spiral manner. The carrier magnet 81 is arranged in a way such that the roller side magnets 82 are facing the holder side magnets 96 across the bulkhead 83. The bulkhead 83 is made of a material with high magnetic permeability, and the holder side magnets 96 and the roller side magnets 82 are magnetically connected through the bulkhead 83. Meanwhile, the space on the substrate holder 90 side of the bulkhead 83 (i.e. inside each vacuum chamber) is vacuum, while the space on the carrier magnet 81 side of the bulkhead 83 is air. Such carrier magnets 81 are arranged along the square form traveling path 80 shown in FIG. 4.

As shown in FIG. 6, the substrate holder 90 is mounted on a main pulley 84 which rotates about a horizontal rotation axis. The main pulleys 84 are provided in a large number along the traveling direction of the substrate holder 90. In addition, the lower end portion of the substrate holder 90 is connected to a pair of sub-pulleys 85 and 85 which rotate about vertical axes. These sub-pulleys 85 and 85 hold the lower end portion of the substrate holder 90 in a way sandwiching the lower end portion from both ends so as to prevent the substrate holder 90 from tilting. These sub-pulleys 85 and 85 are also provided in a large number along the traveling direction of the substrate holder 90. As shown in FIG. 6, a driving rod 86 is attached to the carrier magnet 81 through a bevel gear. A driving motor 87 is being connected to the driving rod 86, whereby the carrier magnet 81 is made to rotate about its central axis through the driving rod 86.

When the carrier magnet 81 rotates, the roller side magnets 82 of duplex spiral as shown in FIG. 5 will also rotate. At this time, from the holder side magnets' 96 point of view, the rotating roller side magnets 82 will look as though a plurality of magnets having alternately different polarities are lined up and moving linearly in one in the arranging direction. Therefore, the holder side magnets 96 being magnetically connected with the roller side magnets 82 will also move linearly corresponding to the rotation of the roller side magnets 82. As a result, the substrate holder 90 as a whole will move linearly. At this time, the sub-pulleys 85 and 85 will move accordingly as shown in FIG. 6.

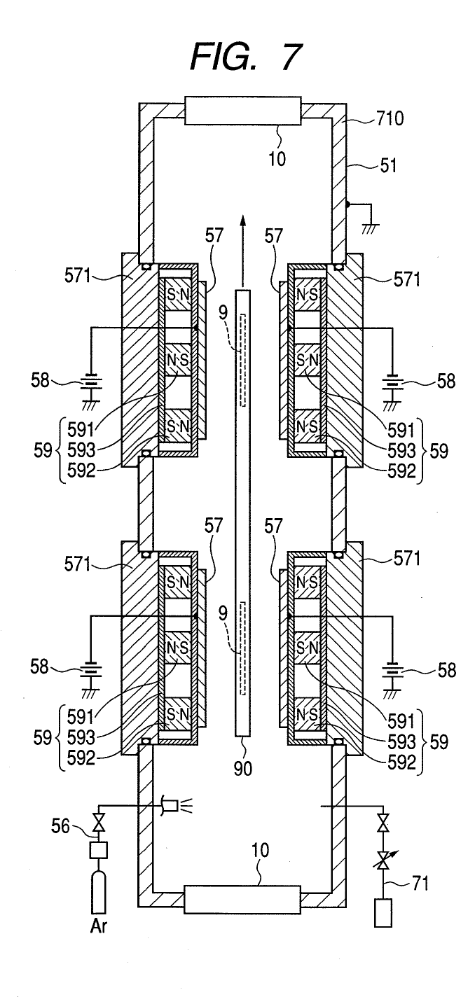

FIG. 7 is a schematic sectional side view explaining a structure of the film delamination preventing chamber 70 as provided in the apparatus shown in FIG. 4. Like the processing chambers, etc. mentioned above, the film delamination preventing chamber 70 is also a gas tight vacuum chamber. The film delamination preventing chamber 70 has an exhaust system 71. The exhaust system 71 is structured in a way such that it should be capable of exhausting gas to bring the pressure inside the film delamination preventing chamber 70 to the extent of about 1×10⁻⁶ Pa. The film delamination preventing chamber 70 is provided with a gate valve 10 at each end.

A film coating means is structured in a way including a gas introducing system 56 for introducing a processing gas inside the chamber, targets 57 having their sputtering surfaces being exposed to the space inside the chamber, sputtering power sources 58 for applying voltage for sputtering discharge to targets 57, and magnets mechanisms 59 provided at the back of respective targets 57. In the present embodiment, tantalum (Ta) is used as a material of the target 57. Other than this, it is also possible to use titanium (Ti), zirconium (Zr), hafnium (Hf), vanadium (V), niobium (Nb), chromium (Cr), molybdenum (Mo), tungsten (W), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al), gallium (Ga), indium (In), carbon (C), magnesium (Mg), silicon (Si), manganese (Mn), or the like, as a material of the target 57.

The exhaust system 71 is capable of exhausting gas to bring the pressure inside the film delamination preventing chamber 70 to the extent of about 1×10⁻⁶ Pa. The gas introducing system 56 is structured in a way such that a processing gas such as argon, etc. can be introduced with a predetermined flow rate. Each of the sputtering power sources 58 is structured in a way such that a negative high voltage of about −300 V to −500 V can be applied to the target 57. Each of the magnets mechanisms 59 functions to enable magnetron discharge, and it is structured in a way including a center magnet 591, a ring shaped peripheral magnet 592 surrounding the center magnet 591, and a plate-like yoke 593 connecting between the center magnet 591 and the peripheral magnet 592. Each of the targets 57 and the magnets mechanisms 59 are fixed to the film delamination preventing chamber 70 through an insulating block 571. The film delamination preventing chamber 70 is electrically grounded.

While the processing gas is introduced by the gas introducing system 56, the pressure inside the film delamination preventing chamber 70 is kept to a predetermined pressure by the exhaust system 71. Each of the sputtering power sources 58 is to be operated under such state. As a result, sputtering discharge will occur whereby the target 57 is to be sputtered and Ta as being a material of the sputtered target 57 is to reach the substrate holder 90 and the substrate holding nails 91 to form coating films of Ta on the surfaces of the substrate holder 90 and the holding nails 91. As shown in FIG. 7, the target 57, the magnets mechanism 59 and the sputtering power source 58 make a set, and such sets are provided on both sides of the film delamination preventing chamber 70 across the substrate holder 90 and the holding nails 91 inside the film delamination preventing chamber 70. Accordingly, coating films are formed on both sides of the substrate holder 90 and the holding nails 91 at the same time. As shown in FIG. 7, the substrate holder 90 is positioned to come in front of the targets 57, and thus the entire substrate holder 90 is to be coated.

### SECOND EMBODIMENT

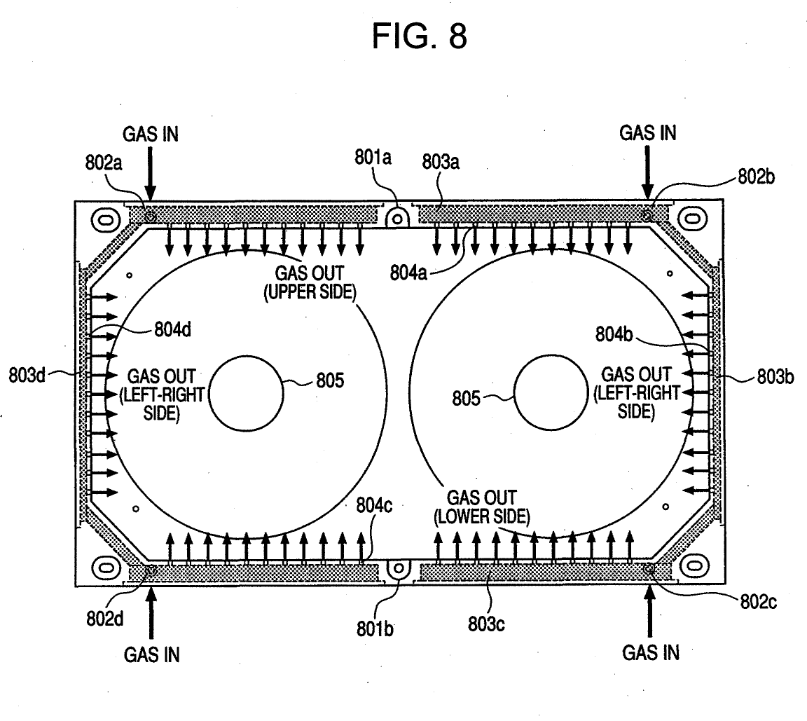

FIG. 8 is a diagram showing a case in which another additional gas inlet port is newly provided in addition to the gas inlet port of the first embodiment. FIG. 8 is a sectional view of a gas introducing mechanism 800 when viewed from a direction perpendicular to the surface of a substrate 805. As shown in FIG. 8, there are four gas introducing routes 803a to 803d, and those gas introducing routes 803a to 803d are provided with gas jetting ports 804a to 804d arranged at a plurality of places surrounding both of the two substrates 805. In the gas introducing mechanism 800 shown in FIG. 8, a gas inlet port 801a and gas introduction connecting ports (Gas IN) 802a and 802b are provided in the upper unit, and in addition, a gas inlet port 801b and gas introduction connecting ports 802c and 802d are also provided in the lower unit. The gas introduction connecting ports 802a and 802b are provided in the gas introducing route 803a, whereas the gas introduction connecting ports 802c and 802d are provided in the gas introducing route 803c. A processing gas entering from the gas introduction connecting ports 802a to 802d is to flow along the gas introducing routes 803a to 803d, and jet out onto the substrates 805 from the gas jetting ports 804a to 804d provided on the gas introducing routes 803a to 803d. Thus, by uniformizing the flowability of gas in this way, it is possible to form films with high uniformity.

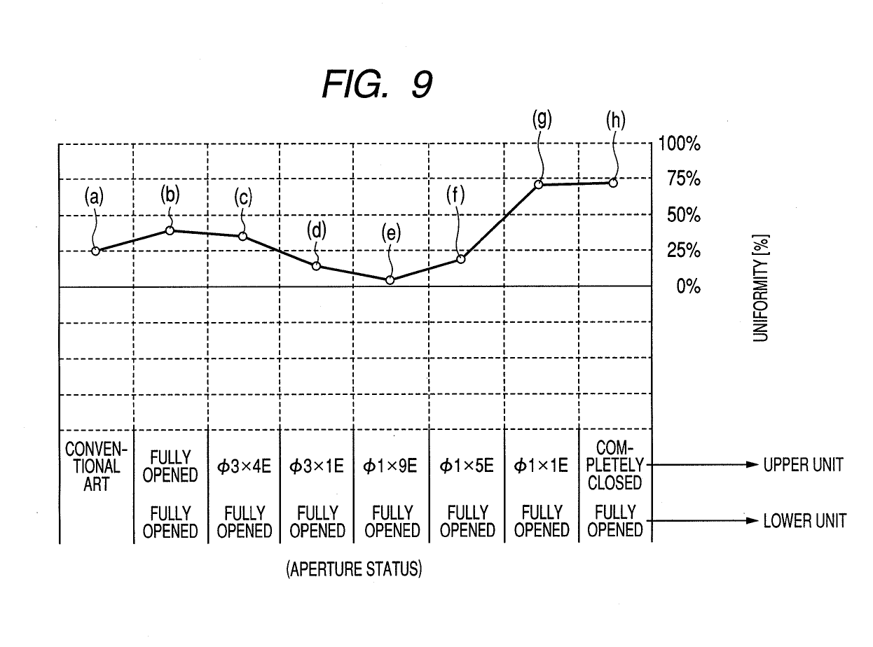

FIG. 9 is a diagram specifically showing changes in uniformity (%) of a produced thin film based on changes in the number and apertures (mm) of gas jetting ports provided in the upper unit gas introducing route and the lower unit gas introducing route of the gas introducing mechanism, respectively. Here, uniformity of the thin film indicates uniformity with respect to the thin film coercivity (H_{c}). That is, uniformity (%) is defined as a percentage of a value that can be obtained by subtracting the minimum coercivity (H_{c} min) from the maximum coercivity (H_{c} max) of the thin film, with respect to a value that can be obtained by adding the maximum coercivity (H_{c} max) and the minimum coercivity (H_{c} min) of the thin film. In FIG. 9, a value of a) represents uniformity of a thin film formed based on the conventional art as disclosed in the above-mentioned Patent Document 3, whereas values of b) to h) represent uniformities of thin films formed according to the present invention. The gas introducing mechanism of the present embodiment is the same as the one described with reference to FIG. 1. That is, in the gas introducing mechanism of the present embodiment, there are 11 gas jetting ports being provided with respect to each of the gas introduction connecting ports in the upper unit gas introducing route, while there are a total of 25 gas jetting ports being provided in the lower unit gas introducing route. There are two substrates being held in the gas introducing mechanism, and the gas introducing mechanism is structured in a way such that a gas can be supplied to each of the substrates mainly by 11 of the gas jetting ports provided in the upper unit gas introducing route and by 12 of the gas jetting ports provided in the lower unit gas introducing route. The value of b) represents uniformity of a thin film that can be realized in a case where 11 of the gas jetting ports each with a 3 mm aperture in the upper unit gas introducing route are opened (fully opened) and 12 of the gas jetting ports each with a 3 mm aperture in the lower unit gas introducing route are all opened (fully opened). The value of c) represents uniformity of a thin film that can be realized in a case where four of the gas jetting ports each with a 3 mm aperture in the upper unit gas introducing route are opened and 12 of the gas jetting ports each with a 3 mm aperture in the lower unit gas introducing route are all opened. The value of d) represents uniformity of a thin film that can be realized in a case where one of the gas jetting ports with a 3 mm aperture in the upper unit gas introducing route is opened and 12 of the gas jetting ports each with a 3 mm aperture in the lower unit gas introducing route are all opened. The value of e) represents uniformity of a thin film that can be realized in a case where nine of the gas jetting ports each with a 1 mm aperture in the upper unit gas introducing route are opened and 12 of the gas jetting ports each with a 3 mm aperture in the lower unit gas introducing route are all opened. The value of f) represents uniformity of a thin film that can be realized in a case where five of the gas jetting ports each with a 1 mm aperture in the upper unit gas introducing route are opened and 12 of the gas jetting ports each with a 3 mm aperture in the lower unit gas introducing route are all opened. The value of g) represents uniformity of a thin film that can be realized in a case where one of the gas jetting ports with a 1 mm aperture in the upper unit gas introducing route is opened and 12 of the gas jetting ports each with a 3 mm aperture in the lower unit gas introducing route are all opened. The value of h) represents uniformity of a thin film that can be realized in a case where 12 of the gas jetting ports in the upper unit gas introducing route are all closed (completely closed) and 12 of the gas jetting ports each with a 3 mm aperture in the lower unit gas introducing route are all opened.

As can be noted, the uniformity of the thin film formed based on the conventional art as disclosed in Patent Document 3 is about 25%, whereas the uniformities in the cases of d), e) and f) with respect to the present embodiment, for instance, are quite less than 25%, suggesting that the film uniformities are improved. In this way, by appropriately adjusting the number and sizes, and further the shapes and orientations of the gas jetting ports provided in the gas introducing routes, it is possible to improve the film uniformity.

The above-described embodiments of the present invention are not intended to limit the scope of the present invention, while they can be modified where appropriate, with the hope of realizing the subject matter of the claims of the present invention, based on the teachings and suggestions that the embodiments can provide.

What is claimed:

1. Sputtering apparatus comprising:
a substrate holding unit for holding a substrate, and
gas introducing routes provided on both surface sides of the substrate, each gas introducing route being arrange to surround the whole periphery of the substrate,
wherein a plurality of gas jetting ports and a gas introduction connecting port are provided on each of said gas introducing routes, and
the gas jetting ports are provided in a higher density as the length between the gas jetting port and the gas introduction connection port becomes longer.

2. The sputtering apparatus according to claim 1, characterized in that the substrate holding means holds a plurality of substrates on the same plane.

3. The sputtering apparatus according to claim 1, characterized in that the number, sizes, shapes and orientations of the gas jetting ports are adjustable.

4. The sputtering apparatus according to claim 1, characterized in that target placement tables are arranged on opposing sides of the substrate holding means.

5. A thin film forming apparatus comprising:
a film forming processing chamber provided with the sputtering apparatus according to claim 1; and
at least one vacuum processing chamber from among a physical vapor deposition (PVD) chamber, a chemical vapor deposition (CVD) chamber, a physical etching chamber, a chemical etching chamber, a substrate heating chamber, a substrate cooling chamber, an oxidation treatment chamber, a reduction treatment chamber and an ashing chamber, the thin film forming apparatus characterized by
the film forming processing chamber and at least one vacuum processing chamber being connected without being exposed to air.

6. A reactive sputtering method, comprising the steps of:
supplying inside a vacuum chamber with an inactive gas by the sputtering apparatus according to claim 1;
making the inactive gas to be plasma discharged;
sputtering a target; and
supplying inside the vacuum chamber with a reactive gas by the sputtering apparatus.

7. Sputtering apparatus comprising:
a substrate holding unit for holding a substrate, and
gas introducing routes provided on both surface sides of the substrate, each gas introducing route being arrange to surround the whole periphery of the substrate,
wherein a plurality of gas jetting ports and a gas introduction connecting port are provided on each of said gas introducing routes, and
the aperture size of the gas jetting ports are larger as the length between the gas jetting port and the gas introduction connection port becomes longer.

8. The sputtering apparatus according to claim 7, characterized in that the substrate holding means holds a plurality of substrates on the same plane.

9. The sputtering apparatus according to claim 7, characterized in that the number, sizes, shapes and orientations of the gas jetting ports are adjustable.

10. The sputtering apparatus according to claim 7, characterized in that target placement tables are arranged on opposing sides of the substrate holding means.

11. A thin film forming apparatus comprising:
a film forming processing chamber provided with the sputtering apparatus according to claim 7; and
at least one vacuum processing chamber from among a physical vapor deposition (PVD) chamber, a chemical vapor deposition (CVD) chamber, a physical etching chamber, a chemical etching chamber, a substrate heating chamber, a substrate cooling chamber, an oxidation treatment chamber, a reduction treatment chamber and an ashing chamber, the thin film forming apparatus characterized by
the film forming processing chamber and at least one vacuum processing chamber being connected without being exposed to air.

12. A reactive sputtering method, comprising the steps of:
supplying inside a vacuum chamber with an inactive gas by the sputtering apparatus according to claim 7;
making the inactive gas to be plasma discharged;
sputtering a target; and
supplying inside the vacuum chamber with a reactive gas by the sputtering apparatus.
